(19) United States
(12) Patent Application Publication
(10) Pub. No.: US 2006/0233393 A1
(43) Pub. Date: Oct. 19, 2006

(54) Digital volume control circuit and method calibrated in decibels

(75) Inventors: Simon Damphousse, Kelowna (CA); Dustin Forman, Kelowna (CA)

Correspondence Address: STEVENS LAW GROUP, P.O. BOX 1667, SAN JOSE, CA, 95109, US

(73) Assignee: ESS Technology, Inc., Fremont, CA (US)

(21) Appl. No.: 11/238,443

(22) Filed: Sep. 28, 2005

Related U.S. Application Data
(60) Provisional application No. 60/671,382, filed on Apr. 14, 2005.

(51) Int. Cl. H03G 3/00

(52) U.S. Cl. 381/104

(57) ABSTRACT

A system and corresponding method is provided for digitally controlling the volume of an audio signal having a series of arithmetic units configured with combinatorial logic to operate in response to control signals to produce a digital output signal amplified in a predetermined manner to digitally control the volume.

### RELATED APPLICATIONS

This application claims priority based on U.S. Provisional Application No. 60/671,382, filed on Apr. 14, 2005.

### BACKGROUND

Many conventional volume control circuits exist in the art. Most conventional volume controls are controlled by an analog resistor, where the turn of a dial or other adjustment device changes the resistance in the circuit, allowing a user to adjust the volume in the speakers. Some circuits are digitally controlled, but they adjust in a similar manner. The adjustment is done in a substantially linear manner, increasing or decreasing the volume as a user adjusts the circuit by multiplying or dividing the volume control signal. The problem with such methods is that it is not pleasing to the listener. The reason it is not pleasant is that a human is able to hear in an exponential manner, where a listener reacts to a change in volume in the form of feedback of sound, which is measured in decibels. Using conventional circuits, the amount in which a user changes the volume of a system does not naturally correspond with the change in actual volume in decibels.

It would be useful if a volume control were implemented as a digital volume control with a specialized circuit. Moreover, particularly in modern music and video systems, there is a need to implement the volume control calibrated in dB. Such a device would be more pleasant to use and would be an ideal setup for a comprehensive sound system, such as for example home theater. As will be seen, the invention provides such a system in an elegant manner.

### DETAILED DESCRIPTION

The method consists of a processor that can multiply input data and obtain the correct level of volume. The system requires a discrete step change measured in decibels (dB), giving a more pleasant listening experience for a user. Furthermore, in comparison to conventional methods that require a single full multiplier for adjusting the volume of a system, simplifications of the volume control circuit can be achieved and integrated into a specialized circuit. In prior art systems, a full multiplier is used for volume control. In contrast, a system configured according to the invention uses fixed multipliers, thus a circuit configured according to the invention will be smaller in size. And, a circuit configured according to the invention does not require a faster clock to calculate intermediate values, as it is fully combinational. In contrast to conventional systems, it can run at the clock speed of the system, greatly simplifying its implementation.

In one embodiment, the circuit works with a series of fixed multipliers. When cascaded, they can produce the full range of values required for a volume control calibrated in dB. In one embodiment, the minimal number of fixed multipliers would correspond to:
M=+/−{1, 3¹, 3², . . . 3ⁿ}
where n is an integer.
The total range for such a configuration is:
RANGE=sum(abs(M))

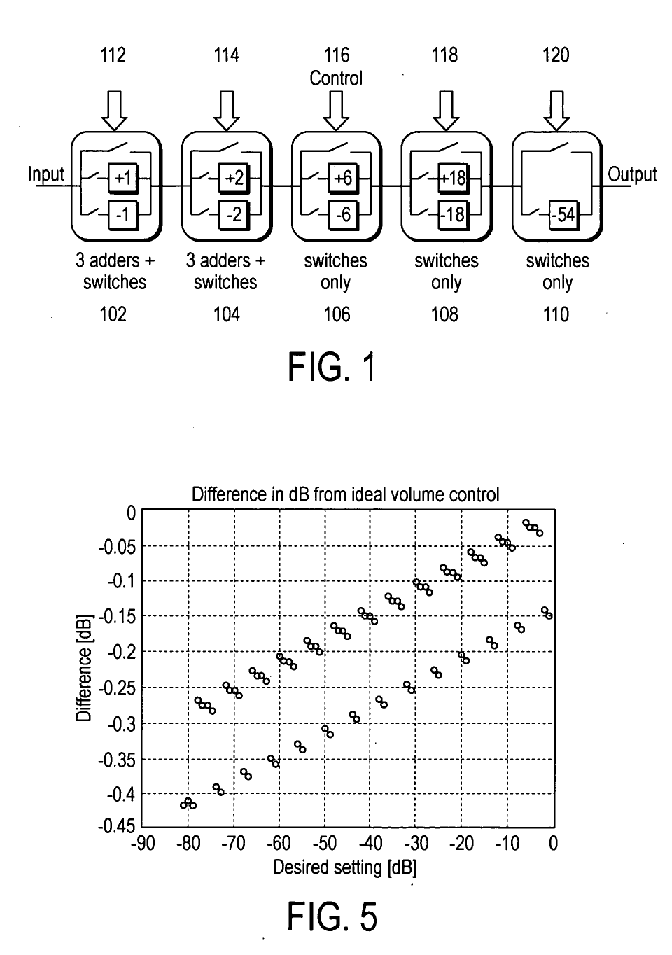

For example, referring to FIG. 1, one embodiment is illustrated where multipliers are set to perform volume control, where the set of {+1, −1, +3, −3, +9} measured in dB could represent multiplication in a range of 1 to 13 dB. The adjustments are of the set {+1, +3−1, +3, +3+1, +9−3−1, +9−3, +9−3+1, +9−1, +9, +9+1, +9, +3−1, +9+3, +9+3+1}. Since a circuit configured according to the invention represents the numbers in base two, it is convenient to use multiple of 6 dB for multiplication (multiplied by 2 or divided by 2). Accordingly, the number of blocks may be set to:
M={+1, −1, +2, −2, +6, −6, +18, −18, −54}
The embodiment of the novel system is further configured to add 0 (zero) dB by adding a bypass switch to each of those blocks The purpose of bypassing any one of the blocks is that any volume level on the dB step can be achieved by selecting the fixed multiplier block. Sometimes, it is required to have only a few blocks in order to meet the required level. Hence a bypass switch is used. Also, since all the signal routing is simply done with switches, the circuit is greatly simplified in its electronic circuit complexity. Also, the settings are independent of time and change only when the user decides to do so by changing the volume control. This series of multipliers can adjust the volume control between 0 and −81 dB, which is largely sufficient for about any application in audio. For example, −23 dB would be produce by −18−6+1. The multiplier used to perform +/−6, +/−18 and −54 uses multiplexer only. +/−1 and +/−2 uses adders. Since small value in dB are used, further simplification can be achieved in the number of adders used.

In this embodiment, still referring to FIG. 1, the system 100 includes five arithmetic blocks, 102, 104, 106, 108, 110, configured in series to perform the different levels of volume settings. The blocks are configured to receive individual control signals, 112, 114, 116, 118, 120, respectively. Those skilled in the art will understand that this example is merely illustrative of the invention, ant that other specific numbers of blocks and different settings are possible to design a system for a particular application or set up. The invention is not limited to the five block implementation illustrated here, but is only limited to the appended claims.

The first block, 102, Block #1, provides adjustment for the +1 or −1 dB range, and is calculated according to the following formulae:
+1 dB=>x+⅛x− 1/256x
−1 db=>x−⅛x+ 1/64x
In such a block, the circuit can be implemented using three adders with switches. Also, the adjustment of +/− 1/8 can be implemented solely with switches.

The second block, 104, Block #2, provides adjustment for the +2 or −2 dB range, and is calculated according to the following formulae:
+2 dB=>x+¼x+ 1/128x
−2 dB=>x−¼x+ 1/32x
In such a block, the circuit can be implemented using three adders with switches.

The third block, 106, Block #3, provides adjustment for the +6 or −6 dB range, and is calculated using simply a one digital register shift over left or right.

The fourth block, 108, Block #4, provides adjustment for the +18 or −18 dB range, and is calculated by using three logical register shifts.

The fifth and final block of this example embodiment, 110, Block #5, provides the adjustment for the −54 dB level. This adjustment is performed by a switch used to either bypass or enable the 54 dB control.

A circuit configured according to the invention does not require a faster clock to calculate intermediates value, as it is fully combinational. It can run at the clock speed of the system.

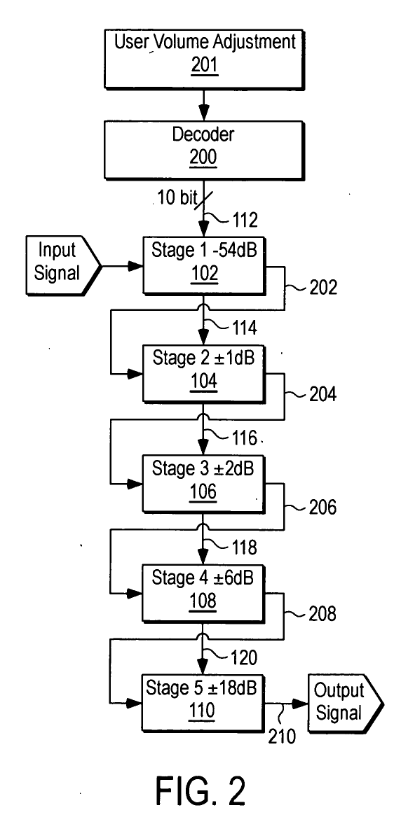

Referring to FIG. 2, one embodiment of a system having a decoder 200 input is illustrated. The decoder 200 is configured to receive a signal from a user volume adjustment module 201. The signal may be a multi-bit digital signal that represents a digital number value, such as a 10 bit signal 112. Other types of signals are possible, and depend on the particular embodiment and the manner in which the adjustment circuit and the decoder operate together. In operation, the first stage receives an audio input signal and a decoder input signal. The stage circuit operates to modify the volume of the signal according to the decoder signal input. If the decoder input indicates a −54 dB change in the volume, then the first stage circuit adjusts the signal accordingly. If, however, the decoder signal does not indicate a change in the first stage, then the signal simply passes through to the next stage.

The output signal 202, whether modified by stage 1 or not, is transmitted to stage 2, where a similar process is performed. In stage 2, both audio signal 202 and the decoder signal is received, and the audio signal is modified according to the decoder signal. If the decoder input indicates a + or −1 dB change in the volume, then the first stage circuit adjusts the signal accordingly. If, however, the decoder signal does not indicate a change in the second stage, then the signal simply passes through to the next stage.

The output signal 204, whether modified by stage 2 or not, is transmitted to stage 3, where a similar process is performed. In stage 3, both audio signal 204 and the decoder signal is received, and the audio signal is modified according to the decoder signal. If the decoder input indicates a + or −2 dB change in the volume, then the first stage circuit adjusts the signal accordingly. If, however, the decoder signal does not indicate a change in the third stage, then the signal simply passes through to the next stage.

The output signal 206, whether modified by stage 3 or not, is transmitted to stage 4, where a similar process is performed. In stage 4, both audio signal 206 and the decoder signal is received, and the audio signal is modified according to the decoder signal. If the decoder input indicates a + or −6 dB change in the volume, then the first stage circuit adjusts the signal accordingly. If, however, the decoder signal does not indicate a change in the fourth stage, then the signal simply passes through to the next stage.

The output signal 208, whether modified by stage 4 or not, is transmitted to stage 5, where a similar process is performed. In stage 5, both audio signal 202 and the decoder signal is received, and the audio signal is modified according to the decoder signal. If the decoder input indicates a + or −18 dB change in the volume, then the first stage circuit adjusts the signal accordingly. If, however, the decoder signal does not indicate a change in the fifth stage, then the signal simply passes through to the output stage, where the volume adjusted audio signal is output.

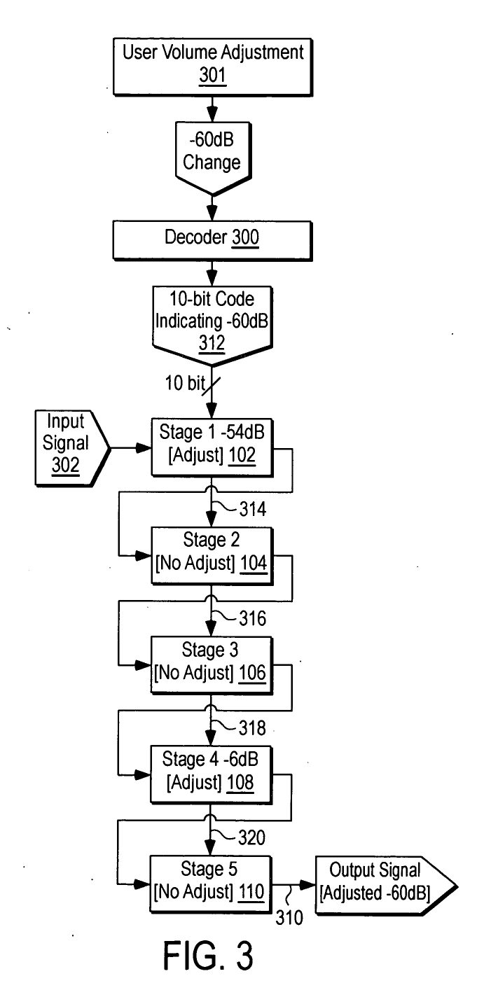

Referring to FIG. 3, one embodiment of a system having a decoder 300 input that receives an adjustment signal 301 is illustrated. A sample signal adjustment of a circuit such as that illustrated in FIG. 3 is illustrated according to the invention.

The decoder 300 is configured to receive a signal from a user volume adjustment module 301. The signal may be a multi-bit digital signal that represents a digital number value, such as a 10 bit signal, 312. Other types of signals are possible, and depend on the particular embodiment and the manner in which the adjustment circuit and the decoder operate together. In operation, the first stage receives an audio input signal and a decoder input signal 312. The stage circuit operates to modify the volume of the signal according to the decoder signal input. The decoder input indicates a −54 dB change in the volume, so the first stage circuit adjusts the signal accordingly. If, however, the decoder signal did not indicate a change in the first stage, then the signal would simply pass through to the next stage.

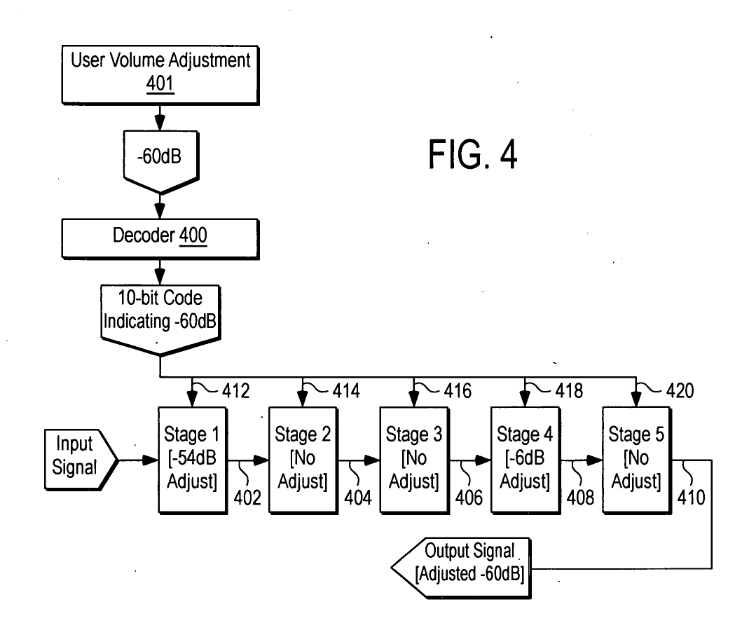

The output signal 302, whether modified by stage 1 or not, is transmitted to stage 2, where a similar process is performed. In stage 2, both audio signal 302 and the decoder signal 314 is received, and the audio signal is modified according to the decoder signal. The decoder may be the same signal 312 received in Stage 1, or may be a separate signal that is pipelined in, such as in a system discussed below and illustrated in FIG. 4. The decoder input does not indicate a + or −1 dB change in the volume, so the second stage circuit does not adjust the signal accordingly, and the signal passed through. If, however, the decoder signal did indicate a change in the second stage, then the signal would be adjusted accordingly, and then transmitted to the next stage.

The output signal 304, whether modified by stage 2 or not, is transmitted to stage 3, where a similar process is performed. In stage 3, both audio signal 304 and the decoder signal 316 is received, and the audio signal is modified according to the decoder signal. The decoder may be the same signal 312 received in Stage 1, or may be a separate signal that is pipelined in, such as in a system discussed below and illustrated in FIG. 4. The decoder input does not indicates a + or −2 dB change in the volume, so the third stage circuit does not adjust the signal accordingly, and the signal passed through. If, however, the decoder signal did indicate a change in the third stage, then the signal would be adjusted accordingly, and then transmitted to the next stage.

The output signal 306, whether modified by stage 3 or not, is transmitted to stage 4, where a similar process is performed. In stage 4, both audio signal 306 and the decoder signal 318 is received, and the audio signal is modified according to the decoder signal. The decoder may be the same signal 312 received in Stage 1, or may be a separate signal that is pipelined in, such as in a system discussed below and illustrated in FIG. 4. The decoder input indicates a + or −6 dB change in the volume, so the fourth stage circuit adjusts the signal accordingly. If, however, the decoder signal did not indicate a change in the fourth stage, then the signal would simply pass through to the next stage.

The output signal 308, whether modified by stage 4 or not, is transmitted to stage 5, where a similar process is performed. In stage 5, both audio signal 308 and the decoder signal 320 is received, and the audio signal is modified according to the decoder signal. The decoder may be the same signal 312 received in Stage 1, or may be a separate signal that is pipelined in, such as in a system discussed below and illustrated in FIG. 4. The decoder input does not indicate a + or −18 dB change in the volume, so the fifth stage circuit does not adjust the signal accordingly, and the signal passed through. If, however, the decoder signal did indicate a change in the fifth stage, then the signal would be adjusted accordingly, and then transmitted to the output stage, where the volume adjusted audio signal is output. In practice, the fine accuracy of the circuit depends only on the accuracy of the +/−1 and +/−2 dB block. The adders employed may be calculated with a simple algorithm. Also, since the dB value is small, the main term of the sum is the same but with an inverse sign. The accuracy of the circuit in getting the right level depends on the +/−1 and +/−2 dB, since the other steps used in the system are exact. For example, 6, 18, and 54 are all multiples of 6 dB, which is achieved with simple logical shift operation. Since the circuit must do +1 and −1 dB, one can save adders when doing add and shift, because both operations require ⅛ of the input signal.

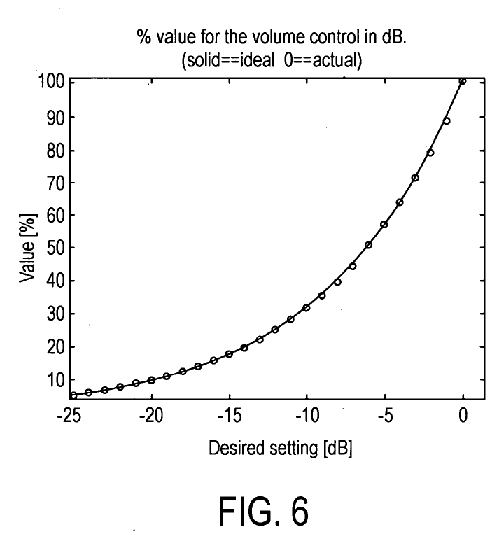

In another embodiment, to provide higher speed, a pipelined configuration is provided to increase the speed of the circuit. Referring to FIG. 4, such a system is illustrated. Referring to FIGS. 5 and 6, graphs are shown to illustrate the accuracy of such a circuit relative to the exact equation. In FIG. 5, the graph shows the difference in decibels, dB, between the ideal setting and a circuit using the invention for each step.

In FIG. 6, a solid line shows the percentage of the input to be used to generate the actual reduction in dB. The “round” object on the graph shows the value that the invention produced. The match is substantial.

The invention has been described in the context of a system and method for digital volume control. Those skilled in the art will understand that other insubstantial variations are possible without departing from the spirit and scope of the invention, which is defined by the appended claims and their equivalents.

1. A system for digital control of audio volume comprising a series of arithmetic units configured with combinatorial logic and configured to operate in response to control signals to produce a digital output signal amplified in a predetermined manner to digitally control the volume.

2. A system according to claim 1, wherein the series of arithmetic units are each configured with a unique predetermined mathematical operation to control the volume of an audio signal.

3. A system according to claim 1, wherein the series of arithmetic units are each configured with a unique and fixed mathematical operation to control the volume of an audio signal according to control signals generated by a user volume adjustment.

4. A system according to claim 1, wherein the system includes a processor configured to receive a digital audio signal and to change a digital value in the signal according to a setting.

5. A system according to claim 1, wherein the system includes a processor configured to receive a digital audio signal and to change a digital value in the signal according to a predetermined setting related to the volume of an audio output signal.

6. A system according to claim 1, wherein the system includes a processor configured to generate control signals to control the individual arithmetic units, where the arithmetic units are configured to receive a digital audio signal and to change values in the signal in response to the control signals

7. A system according to claim 4, wherein the processor is configured to cause the volume of a digital audio signal to change according to a predetermined setting.

8. A system according to claim 5, wherein the processor is configured to cause the volume of a digital audio signal to change according to a predetermined setting related to the volume of an audio output signal.

9. A system configured to digitally control the amplification of a signal comprising:
a series of arithmetic units configured to receive individual control signals corresponding to a predetermined level of volume; and
a corresponding series of adjustment circuits each configured to adjust the signal in response to a control signal.

10. A system configured to digitally control the amplification of a signal comprising:
a series of arithmetic units configured to receive individual control signals corresponding to a desired level of volume; and
a corresponding series of adjustment circuits each configured with logic components to adjust a component of the signal in response to a control signal.
